(19) United States
(12) Patent Application Publication
(10) Pub. No.: US 2016/0356813 A1
(43) Pub. Date: Dec. 8, 2016

(54) TEST DEVICE FOR INTERFACE AND ELECTRONIC DEVICE ASSEMBLY

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: XIAO-YONG MA, Wuhan (CN); LI-FEN YANG, Wuhan (CN)

(21) Appl. No.: 14/790,834

(22) Filed: Jul. 2, 2015

(30) Foreign Application Priority Data
Jun. 5, 2015 (CN) 201510304031.0

(51) Int. Cl. G01R 1/04

(52) U.S. Cl. CPC G01R 1/0408

(57) ABSTRACT

A test device for an interface which can test the performance of an interface of an electronic product is provided. The test device includes a securing module configured to secure the electronic product and an adjustment module. The securing module includes a shell and a securing member configured to be secured in the shell. The adjustment module includes two adjustment members slidably installed in the shell and a test card mounted on the adjustment member. The adjustment members are slidable relative to the shell to align the test card with the interface, and the test card is configured to be inserted into and extracted from the interface for testing.

### CROSS-REFERENCE TO RELATED APPLICATIONS

This application claims priority to Chinese Patent Application No. 201510304031.0 filed on Jun. 5, 2015, the contents of which are incorporated by reference herein.

### FIELD

The subject matter herein generally relates to test devices and electronic device assemblies, and more particularly to a test device and an electronic device assembly for an extension card interface.

### BACKGROUND

Electronic products, such as, smart phones and tablet computers includes a plurality of interfaces for receiving expansion cards. Testing the performance of the interfaces after the electronic products have been completely assembled is usually required.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric, exploded view of an embodiment of a test device and a test member.

FIG. 2 is an isometric, exploded view of an adjustment module of the test device of FIG. 1.

FIG. 3 is an isometric, assembled view of the interface test device and the test member of FIG. 1.

FIG. 4 is similar to FIG. 3, but viewed from another angle.

FIG. 5 is a cross sectional view of line V-V of FIG. 4.

FIG. 6 is an isometric, assembled view of the test device, the test member, and an electronic product.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising” when utilized, means “including, but not necessarily limited to”; it specifically indicates open-ended inclusion or membership in the so-described combination, group, series and the like.

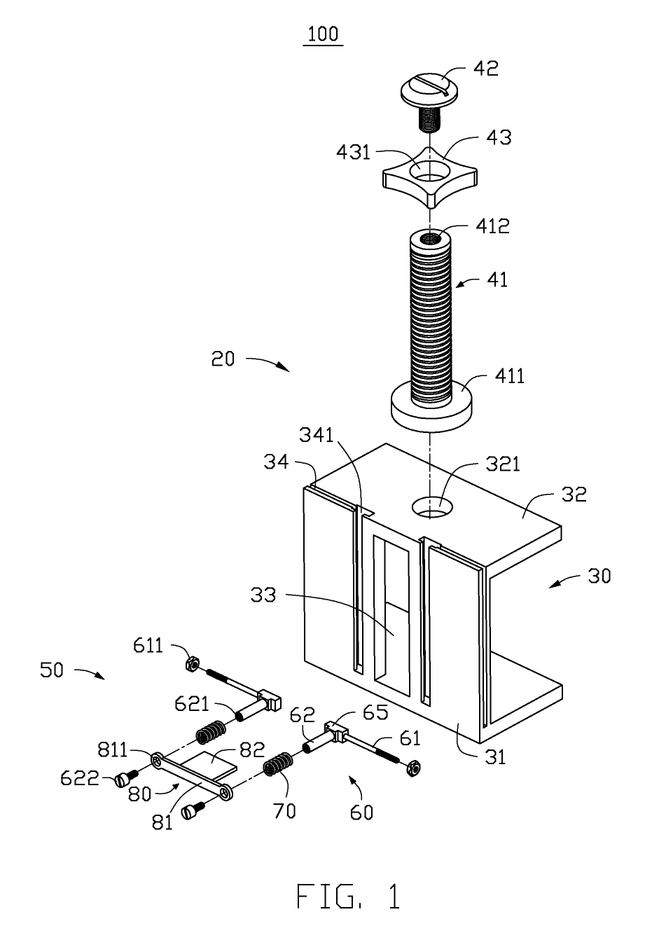

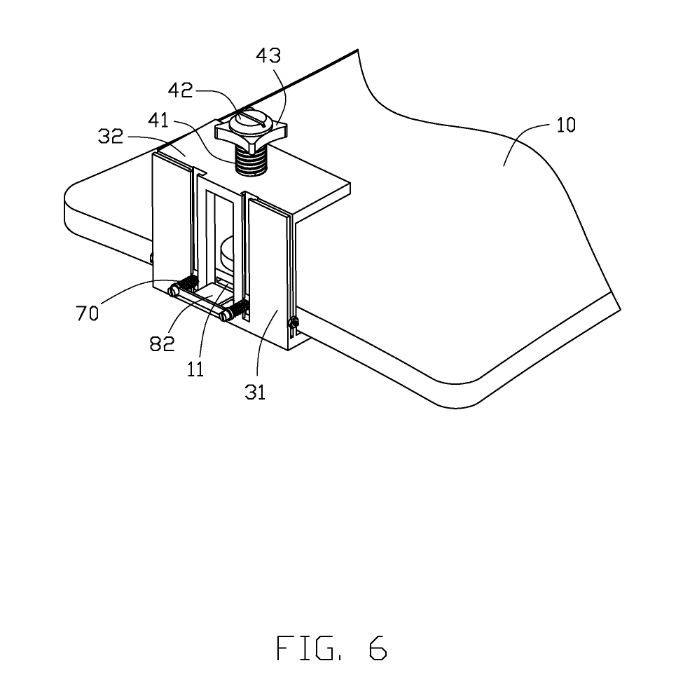

FIGS. 1 and 6 illustrate one embodiment of a test device 100 configured to test the performance of an interface 11 of an electronic product 10. The test device 100 includes a securing module 20 and an adjustment module 50. In at least one embodiment, the electronic product 10 can be a tablet computer.

The securing module 20 includes a shell 30 and a securing member 40 configured to be secured on the shell 30. The shell 30 includes a mounting plate 31 and two parallel side plates 32. The two side plates 32 are substantially perpendicular to the mounting plate 31 and secured on the two ends of the mounting plate 31. The mounting plate 31 defines an opening 33 between the two side plates 32. An interior of the mounting plate 31 defines a receiving space 34 located on each of two sides of the opening 33. The receiving space 34 defines a sliding groove 341 which is substantially parallel to the opening 33. One of the two side plates 32 defines a pivot hole 321.

The securing member 40 includes a bolt 41, a screw 42 and a handle 43. The bolt 41 is configured to pass through the pivot hole 321 and engage with the pivot hole 321 via a threaded engagement. One end of the bolt 41 is equipped with a stop portion 411. A diameter of the stop portion 411 is greater than a diameter of the bolt 41 and a diameter of the pivot hole 321. Another end of the bolt 41 defines a securing hole 412, and the screw 42 is configured to be inserted into the securing hole 412. The handle 43 defines a through hole 431 and the bolt 41 is configured to be inserted into the through hole 431 to secure the handle 43 on the bolt 41.

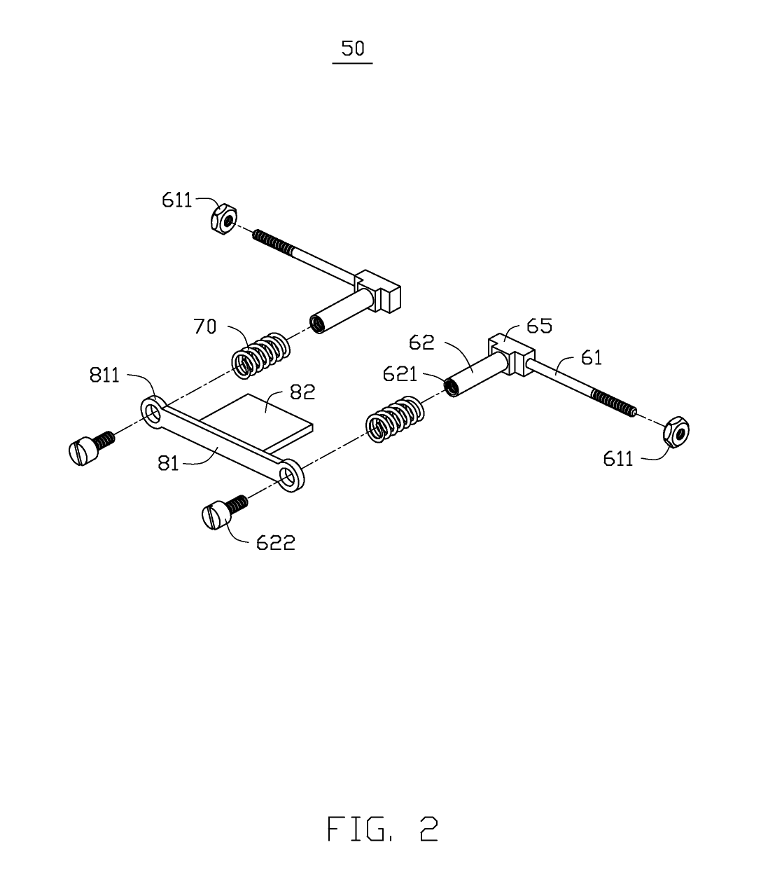

FIGS. 1 and 2 illustrate that the adjustment module 50 includes two adjustment members 60, two resilient members 70 configured to be secured on the adjustment members 60, and a test member 80. The adjustment member 60 includes an adjustment pole 61, a guiding column 62, and a sliding block 65. The adjustment pole 61 is substantially perpendicular to the guiding column 62 and is connected with the guiding column 62 via the sliding block 65. The sliding block 65 is configured to be received in the sliding groove 341 and can slide in the sliding groove 341. One end of the adjustment pole 61 is equipped with a nut 611. The nut 611 is configured to be slid into the adjustment pole 61 via the threaded engagement. One end of the guiding column 62 defines a screw hole 621. A fastener 622 is configured to be inserted into the screw hole 621.

The resilient member 70 surrounds the guiding column 62 with one end resisting against the sliding block 65. In at least one embodiment, the resilient member 70 can be a spring. The test member 80 includes a connecting rod 81 and a test card 82 configured to be secured on the connecting rod 81. Each end of the connecting rod 81 is equipped with a ring 811 configured to be set on the guiding column 62. A size of the test card 82 is substantially same as a size of the interface 11 and the test card 82 is configured to be inserted into the interface 11.

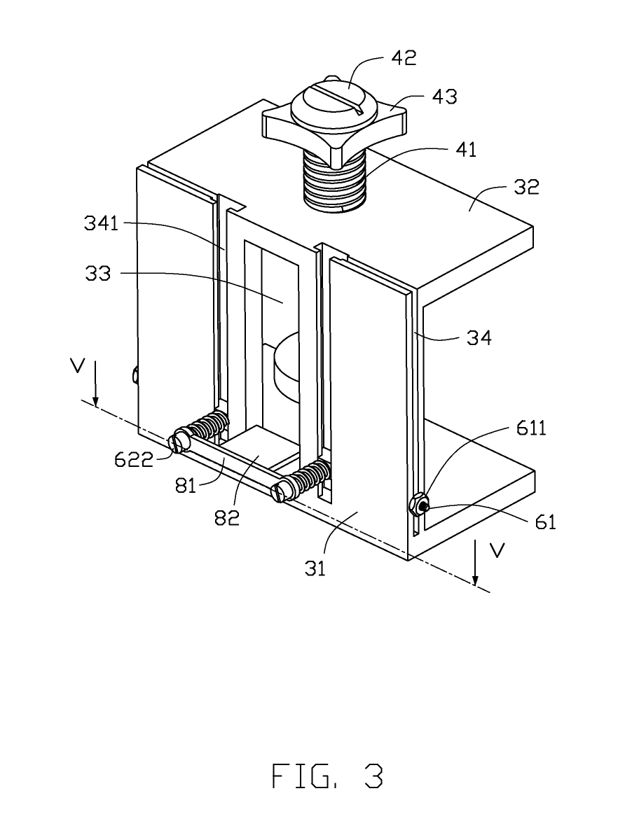

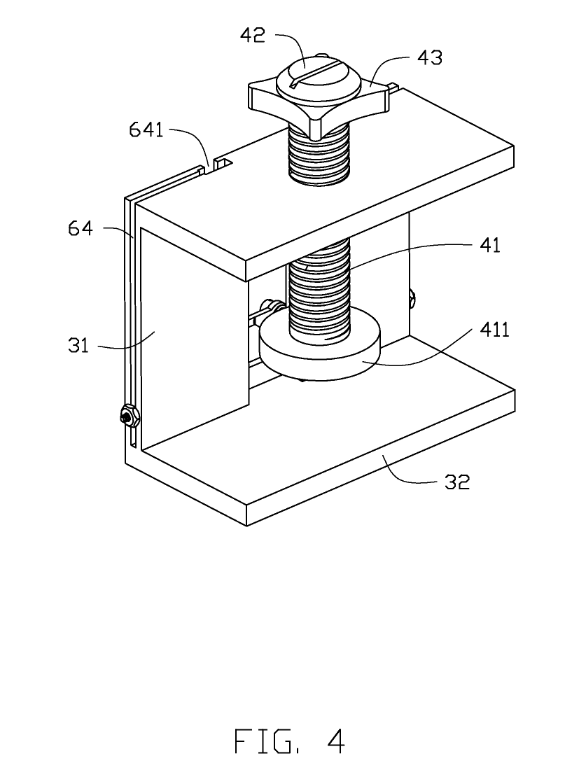

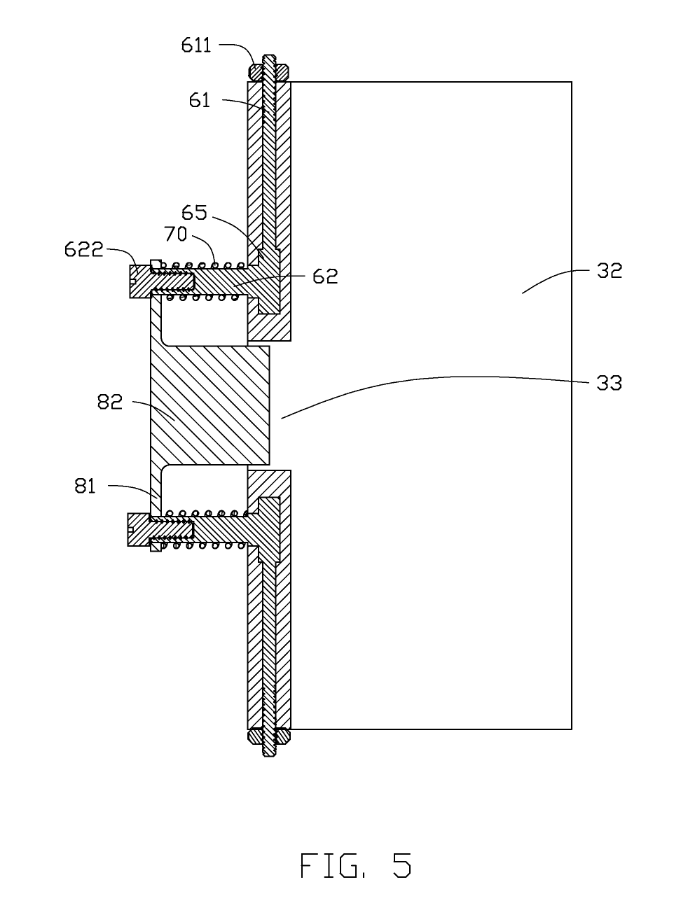

FIGS. 3 to 5 illustrate assembly, the bolt 41 being placed between the two side plates 32 and one end of the bolt 41 inserted into the pivot hole 321. The handle 43 is set on the bolt 41 and the screw 42 is inserted into the securing hole 412. Then, the securing member 40 is installed on the shell and the securing module 20 is completely assembled.

The resilient member 70 surrounds the guiding column 62. The test member 80 is set on the guiding column 62 and the test card 82 faces the direction of the adjustment pole 61. The fastener 622 is inserted into the screw hole 621 to secure the resilient member 70 and the test member 80 on the adjustment member 60. The two adjustment members 60 are placed around the mounting plate 31. The adjustment pole 61 is received in the receiving space 34 and the sliding block 65 is received in the sliding groove 341. The nuts 611 are secured on the adjustment poles 61. Then, the adjustment module 50 is installed on the securing module 20 and the interface test device 100 is completely assembled.

FIG. 6 illustrates the testing of an electronic product 10. The electronic product 10 is placed in the shell 30 and resists against one of the side plates 32. The interface 11 is aligned with the opening 33. The handle 43 is rotated to move the bolt 41 towards the electronic product 10 until the stop portion 411 is attached on the electronic product 10. The electronic product 10 is secured in the test device 100. The adjustment pole 61 is pushed to allow the sliding block 65 to slide in the sliding groove 341. The test member 80 is slid by the sliding block 65 to align the test card 82 with the interface 11, in a direction substantially parallel to the mounting plate 31. The two nuts 611 are rotated to allow the two adjustment poles 61 to slide in the receiving space 34 and to align the test card 82 with the interface 11 in a direction substantially parallel to the side plate 32.

In the test, the test card 82 is pushed towards the interface 11 and the resilient member 70 is elastically compressed, until the test card 82 is configured to be inserted into the interface 11 through the opening 33. When test card 82 is released, the resilient member 70 elastically restores and the test card 82 is disengaged from the interface 11. The process is repeated to complete the testing of the performance of the interface 11.

The embodiments shown and described above are only examples. Many details are often found in the art such as the other features of a test device for interface and electronic device assembly. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A test device for an interface comprising:
a securing module comprising a shell and a securing member configured to be secured in the shell, the securing module configured to be secured to an electronic product having an interface; and
an adjustment module comprising two adjustment members slidably installed in the shell and a test card mounted on the adjustment member, the test card is configured to be inserted into and extracted from the interface;
wherein the adjustment members are slidable relative to the shell to align the test card with the interface.

2. The test device of claim 1, wherein the shell comprises a mounting plate, the mounting plate defines an opening, and the test card is configured to be inserted into the interface by passing through the opening.

3. The test device of claim 2, wherein the mounting plate defines two receiving spaces located on two sides of the opening, and each adjustment member comprises an adjustment pole received in one of the two receiving spaces.

4. The test device of claim 3, wherein each receiving space defines a sliding groove adjacent the opening, the adjustment member further comprises a sliding block secured to an end of the adjustment pole, and the sliding block is slidably received in the sliding groove.

5. The test device of claim 4, wherein each adjustment member further comprises a guiding column substantially perpendicular to the adjustment pole, and the test card is installed in the guiding column.

6. The test device of claim 5, further comprising a connecting rod, wherein each end of the connecting rod is equipped with a ring, and the rings are respectively set on the two guiding columns.

7. The test device of claim 2, wherein the shell comprises two parallel side plates configured to be secured two ends of the mounting plate, and the two side plates are substantially perpendicular to the mounting plate.

8. The test device of claim 7, wherein one of the side plates defines a pivot hole, and the securing member is rotatably installed in the pivot hole.

9. The test device of claim 8, wherein the securing member comprises a bolt, the bolt is threaded with the pivot hole through configured to pass through the pivot hole and be attached with the pivot hole via the thread engagement.

10. The test device of claim 1, wherein the adjustment module further comprises two resilient members secured on the adjustment members, each resilient member can be elastically deformed to drive the test card.

11. An electronic device assembly comprising:
an electronic product defining a interface; and
a test device comprising:
a securing module comprising a shell and a securing member configured to be secured in the shell, the securing module configured to be secured to an electronic product having an interface; and
an adjustment module comprising two adjustment members slidably installed in the shell and a test card mounted on the adjustment member, the test card is configured to be inserted into and extracted from the interface;
wherein the adjustment members are slidable relative to the shell to align the test card with the interface.

12. The electronic device assembly of claim 11, wherein the shell comprises a mounting plate, the mounting plate defines an opening, and the test card is configured to be inserted into the interface by passing through the opening.

13. The electronic device assembly of claim 12, wherein the mounting plate defines two receiving spaces located on two sides of the opening, and each adjustment member comprises an adjustment pole received in one of the two receiving spaces.

14. The electronic device assembly of claim 13, wherein each receiving space defines a sliding groove adjacent the opening, the adjustment member further comprises a sliding block secured to an end of the adjustment pole, and the sliding block is slidably received in the sliding groove.

15. The electronic device assembly of claim 14, wherein each adjustment member further comprises a guiding column substantially perpendicular to the adjustment pole, and the test card is installed in the guiding column.

16. The electronic device assembly of claim 15, further comprising a connecting rod, wherein each end of the connecting rod is equipped with a ring, and the rings are respectively set on the two guiding columns.

17. The electronic device assembly of claim 12, wherein the shell comprises two parallel side plates configured to be secured two ends of the mounting plate, and the two side plates are substantially perpendicular to the mounting plate.

18. The electronic device assembly of claim 17, wherein one of the side plates defines a pivot hole, and the securing member is rotatably installed in the pivot hole.

19. The electronic device assembly of claim 18, wherein the securing member comprises a bolt, the bolt is threaded with the pivot hole through configured to pass through the pivot hole and be attached with the pivot hole via the thread engagement.

20. The electronic device assembly of claim 11, wherein the adjustment module further comprises two resilient members secured on the adjustment members, each resilient member can be elastically deformed to drive the test card.
